(19) United States
(12) Patent Application Publication
(10) Pub. No.: US 2025/0169059 A1
(43) Pub. Date: May 22, 2025

(54) SEMICONDUCTOR DEVICES

(71) Applicant: Samsung Electronics Co., Ltd., Suwon-si (KR)

(72) Inventors: Yangdoo KIM, Suwon-si (KR); Sangwuk PARK, Suwon-si (KR); Minkyu SUH, Suwon-si (KR); Geonyeop LEE, Suwon-si (KR); Dokeun LEE, Suwon-si (KR); Jihye LEE, Suwon-si (KR)

(73) Assignee: Samsung Electronics Co., Ltd., Suwon-si (KR)

(21) Appl. No.: 18/815,929

(22) Filed: Aug. 27, 2024

(30) Foreign Application Priority Data
Nov. 16, 2023 (KR) 10-2023-0159396

(51) Int. Cl. H10B 12/00

(52) U.S. Cl. CPC H10B 12/315; H10D 1/043; H10D 1/716

(57) ABSTRACT

A semiconductor device includes a lower structure including conductive regions; a capacitor including first electrode structures electrically connected to the conductive regions of the lower structure, a dielectric layer covering the first electrode structures, and a second electrode structure on the dielectric layer; and an upper support pattern in contact with the first electrode structures, wherein each of the first electrode structures includes a first electrode region extending vertically; and a second electrode region extending upwardly from the first electrode region and having a side surface not vertically aligned with a side surface of the first electrode region, and wherein the upper support pattern includes a first layer covering upper surfaces of the second electrode regions of the first electrode structures and connected to each other; and a second layer on the first layer and including a material different from a material of the first layer.

### CROSS-REFERENCE TO RELATED APPLICATION(S)

This application claims benefit of priority to Korean Patent Application No. 10-2023-0159396 filed on Nov. 16, 2023 in the Korean Intellectual Property Office, the disclosure of which is incorporated herein by reference in its entirety.

### BACKGROUND

Example embodiments of the inventive concepts relate to a semiconductor device.

As demand for higher performance, speed, and/or multifunctionality of a semiconductor device has increased, integration density of a semiconductor device has also been increased. In manufacturing a semiconductor device having finer patterns in response to the trend of higher integration of a semiconductor device, it may be advantageous to implement patterns having finer widths and/or finer spacing distances.

### SUMMARY

Example embodiments of the inventive concepts provide a semiconductor device including a capacitor having improved reliability.

According to example embodiments of the inventive concepts, a semiconductor device includes a lower structure including conductive regions; a capacitor including first electrode structures electrically connected to the conductive regions of the lower structure, a dielectric layer covering the first electrode structures, and a second electrode structure on the dielectric layer; and an upper support pattern in contact with the first electrode structures, wherein each of the first electrode structures includes a first electrode region extending vertically; and a second electrode region extending upwardly from the first electrode region and having a side surface not vertically aligned with a side surface of the first electrode region, and wherein the upper support pattern includes a first layer covering upper surfaces of the second electrode regions of the first electrode structures and connected to each other; and a second layer on the first layer and including a material different from that of the first layer.

According to example embodiments of the inventive concepts, a semiconductor device includes a lower structure; a capacitor on the lower structure, wherein the capacitor includes first electrode structures, a dielectric layer covering the first electrode structures, and a second electrode structure on the dielectric layer; and an upper support pattern in contact with the first electrode structures, wherein each of the first electrode structures includes a first electrode region extending vertically; and a second electrode region on the first electrode region, wherein the upper support pattern includes a first layer covering upper surfaces of the second electrode regions of the first electrode structures and side surfaces of an upper region of the second electrode region and connected to each other, and wherein the first layer has convex portions having a convex upper surface in a vertical direction away from an upper surface of the lower structure and a concave portion having a concave upper surface between the convex portions.

According to example embodiments of the inventive concepts, a semiconductor device includes a lower structure including a conductive region on a substrate; first electrode structures on a lower structure, electrically connected to the conductive region of the lower structure, and extending in a vertical direction; support patterns in contact with the first electrode structures; a dielectric layer covering the first electrode structures and the support pattern; and a second electrode structure on the dielectric layer, wherein each of the first electrode structures includes a first electrode region and a second electrode region on the first electrode region, wherein the support patterns include an intermediate support pattern in contact with side surfaces of upper regions of the first electrode regions of the first electrode structures; and an upper support pattern in contact with upper surfaces of the second electrode regions of the first electrode structures and side surfaces of upper regions of the second electrode regions of the first electrode structures, and wherein, in each of the first electrode structures, a minimum width of the second electrode region is less than a width of an upper region of the first electrode region.

### BRIEF DESCRIPTION OF DRAWINGS

The above and other aspects, features, and advantages in example embodiments will be more clearly understood from the following detailed description, taken in combination with the accompanying drawings, in which:

FIG. 1 is a plan diagram illustrating a semiconductor device according to example embodiments of the present disclosure;

FIG. 2 is an enlarged diagram illustrating a portion of a semiconductor device according to an example embodiments of the present disclosure;

FIG. 3 is vertical cross-sectional diagrams illustrating a semiconductor device taken along lines I-I′ and II-II′;

FIG. 4 is an enlarged diagram illustrating a portion of a semiconductor device according to an example embodiments of the present disclosure;

FIG. 5 is an enlarged diagram illustrating a portion of a semiconductor device according to an example embodiments of the present disclosure;

FIG. 6 is an enlarged diagram illustrating a portion of a semiconductor device according to an example embodiments of the present disclosure;

FIG. 7 is an enlarged diagram illustrating a portion of a semiconductor device according to an example embodiments of the present disclosure;

FIG. 8 is an enlarged diagram illustrating a portion of a semiconductor device according to an example embodiments of the present disclosure;

FIGS. 9A to 9K are cross-sectional diagrams illustrating a method of manufacturing a semiconductor device according to an example embodiments of the present disclosure;

FIG. 10 is a layout diagram illustrating a semiconductor device according to an example embodiments of the present disclosure; and

FIG. 11 is a semiconductor device according to an example embodiments of the present disclosure.

### DETAILED DESCRIPTION

Hereinafter, example embodiments of the inventive concepts will be described as follows with reference to the accompanying drawings.

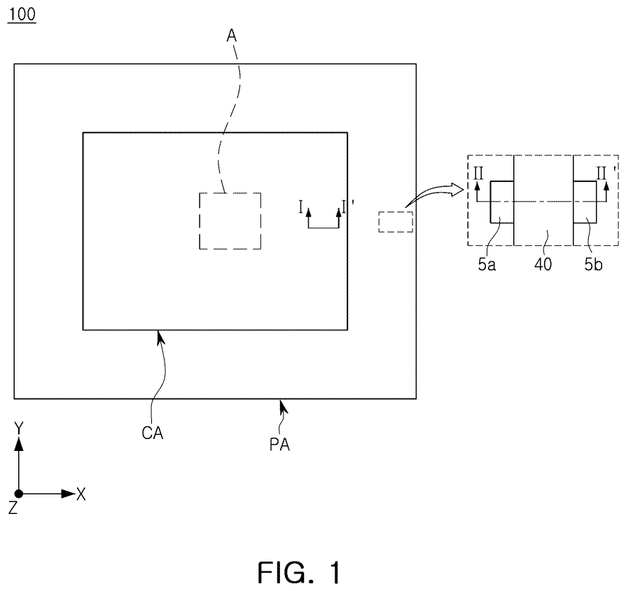

FIG. 1 is a plan diagram illustrating a semiconductor device according to example embodiments.

Referring to FIG. 1, a semiconductor device according to example embodiments may include a cell region CA and a peripheral circuit region PA. The peripheral circuit region PA may be disposed to surround the cell region CA. The cell region CA may refer to a region in which the memory cells of dynamic random access memory (DRAM) devices are disposed, and in the peripheral circuit region PA, a wordline driver, a sense amplifier, row and column decoders and/or control circuits may be disposed. The semiconductor device according to example embodiments may further include an interfacial region disposed between the cell region CA and the peripheral circuit region PA. An interfacial region may be configured to electrically connect the cell region CA to the peripheral circuit region PA.

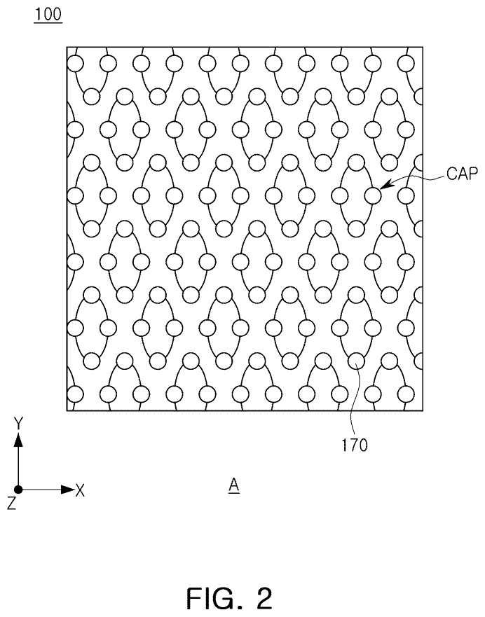

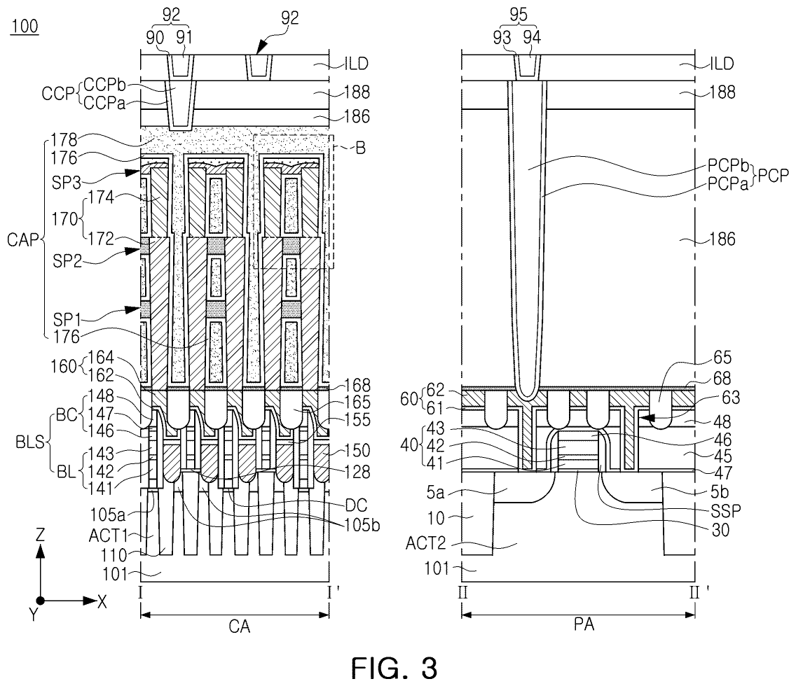

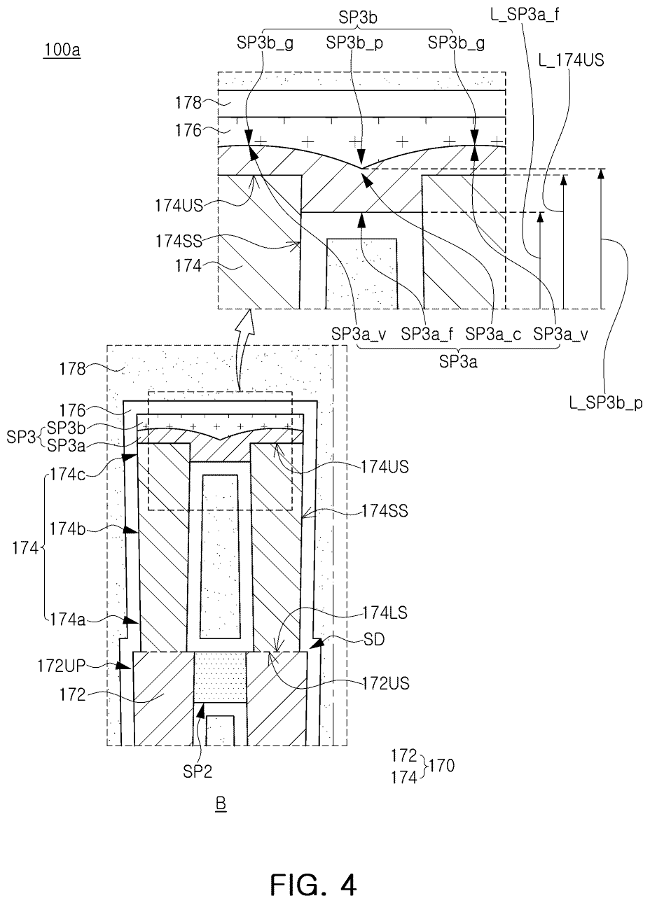

FIG. 2 is an enlarged diagram illustrating a portion of a semiconductor device according to example embodiments, corresponding to region A. FIG. 3 is vertical cross-sectional diagrams illustrating a semiconductor device taken along lines I-I′ and II-II′. FIG. 4 is an enlarged diagram illustrating a portion of a semiconductor device according to example embodiments, corresponding to region B.

Referring to FIGS. 2 and 3, a semiconductor device 100 may include a substrate 101 including a first active regions ACT1 disposed in the cell region CA, a device isolation layer 110 defining first active regions ACT1 with the substrate 101, a bitline structure BLS disposed on the substrate 101 and including a bitline BL, and a data storage structure CAP on the bitline structure BLS. In the cell region CA, the semiconductor device 100 may further include a lower conductive pattern 150 on the first active region ACT1, an upper conductive pattern 160 on the lower conductive pattern 150, and an insulating pattern 165 penetrating the upper conductive pattern 160.

Although not illustrated, the semiconductor device 100 may further include a wordline disposed in the cell region CA and buried in the substrate 101.

For example, the semiconductor device 100 may include a cell array of a dynamic random access memory (DRAM). For example, the bitline BL may be connected to the first impurity region 105a of the first active region ACT1, and the second impurity region 105b of the first active region ACT2 may be electrically connected to the data storage structure CAP on the upper conductive pattern 160 through the lower and upper conductive patterns 150 and 160.

The data storage structure CAP may be configured as a capacitor which may store data in memory such as DRAM. The data storage structure CAP may be electrically connected to conductive regions 150 and 160, for example, on the lower structure including lower and upper conductive patterns 150 and 160. Here, the lower structure may include the substrate 101, the wordline, and the bitline structure BLS.

The data storage structure CAP may include first electrode structures 170, a dielectric layer 176 on the first electrode structures 170, and a second electrode structure 178 on the dielectric layer 176. The data storage structure CAP may further include support patterns SP1, SP2, and SP3. The first electrode structures 170 may be an electrode disposed in a lower portion, and may include a first electrode region 172 and a second electrode region 174 disposed on the first electrode region 172. The second electrode structure 178 may be an electrode disposed in an upper portion. The support patterns SP1, SP2, and SP3 may be disposed between the first electrode structures 170 and may support the first electrode structures 170. The support patterns SP1, SP2, and SP3 may include a plurality of lower support pattern SP1 supporting a region between the first electrode regions 172, an intermediate support pattern SP2, and an upper support pattern SP3 supporting a region between the second electrode regions 174.

The substrate 101 may include a semiconductor material, such as a group IV semiconductor, a group III-V compound semiconductor, or a group II-VI compound semiconductor. For example, a group IV semiconductor may include silicon, germanium, or silicon-germanium. The substrate 101 may further include impurities. The substrate 101 may be implemented as a silicon substrate, a silicon on insulator (SOI) substrate, a germanium substrate, a germanium on insulator (GOI) substrate, a silicon-germanium substrate, or a substrate including an epitaxial layer.

The first active regions ACT1 may be defined in the substrate 101 by the device isolation layer 110. The first active region ACT1 may have first and second impurity regions 105a and 105b at a predetermined or alternatively, desired depth from the upper surface of substrate 101. The first and second impurity regions 105a and 105b may be spaced apart from each other. The first and second impurity regions 105a and 105b may be provided as source/drain regions of the transistor including the wordline. The source region and the drain region may be formed by the first and second impurity regions 105a and 105b by doping or ion implantation of the same or substantially the same impurities, and may be referred to interchangeably depending on a circuit configuration of a finally formed transistor. The impurities may include impurities with a conductivity-type opposite to that of substrate 101. In example embodiments, depths of the first and second impurity regions 105a and 105b in the source region and the drain region may be different.

A device isolation layer 110 may be formed by a shallow trench isolation (STI) process. The device isolation layer 110 may surround the first active regions ACT1 and may electrically isolate the first active regions ACT1 from each other. The device isolation layer 110 may be formed of an insulating material, for example, silicon oxide, silicon nitride, or a combination thereof.

Although not illustrated, the wordline may be disposed to extend in the first direction X across the first active region ACT1. For example, a pair of adjacent wordlines may be disposed to cross a first active region ACT1. A wordline may be included in a gate of a buried channel array transistor (BCAT), but example embodiments thereof are not limited thereto.

The bitline structure BLS may extend perpendicular to the wordline in one direction, for example, in the second direction Y. The bitline structure BLS may include a bitline BL and a bitline capping pattern BC on the bitline BL.

The bitline BL may include a first conductive pattern 141, a second conductive pattern 142, and a third conductive pattern 143, which are sequentially stacked. A bitline capping pattern BC may be disposed on the third conductive pattern 143. A buffer insulating layer 128 may be disposed between the first conductive pattern 141 and the substrate 101, and a portion of the first conductive pattern 141 (hereinafter, referred to as a bitline contact pattern DC) may be in contact with the first impurity region 105a of the first active region ACT1. The bitline BL may be electrically connected to the first impurity region 105a through the bitline contact pattern DC. A lower surface of the bitline contact pattern DC may be disposed on a level lower than a level of an upper surface of substrate 101, and may be disposed on a level higher than a level of an upper surface of the wordline. In example embodiments, the bitline contact pattern DC may be formed in the substrate 101 and may be locally disposed in a bitline contact hole exposing the first impurity region 105a.

The first conductive pattern 141 may include a semiconductor material such as polycrystalline silicon. The first conductive pattern 141 may be in direct contact with the first impurity region 105a. The second conductive pattern 142 may include a metal-semiconductor compound. For example, the metal-semiconductor compound may be a layer formed by siliciding a portion of the first conductive pattern 141. For example, the metal-semiconductor compound may include cobalt silicide (CoSi), titanium silicide (TiSi), nickel silicide (NiSi), tungsten silicide (WSi), or other metal silicide. The third conductive pattern 143 may include a metal material such as titanium (Ti), tantalum (Ta), tungsten (W), and aluminum (Al). The number of conductive patterns included in the bitline BL, type of a material thereof, and/or a stacking order thereof may be varied in example embodiments.

The bitline capping pattern BC may include a first capping pattern 146, a second capping pattern 147, and a third capping pattern 148 stacked sequentially on the third conductive pattern 143. Each of the first to third capping patterns 146, 147, and 148 may include an insulating material, for example, a silicon nitride film. The first to third capping patterns 146, 147, and 148 may be formed of different materials, and even when the first to third capping patterns 146, 147, and 148 include the same material, boundaries therebetween may be distinct due to a difference in physical properties. A thickness of the second capping pattern 147 may be smaller than a thickness of each of the first capping pattern 146 and the third capping pattern 148. The number of capping patterns included in the bitline capping pattern BC and/or a type of material thereof may be varied in example embodiments.

Although not illustrated, spacer structures may be disposed on both sidewalls of each of the bitline structures BLS. The spacer structures may extend in one direction, for example, the Y-direction, on both sidewalls of each bitline structure BLS. The spacer structures may be disposed between the bitline structure BLS and the lower conductive pattern 150. The spacer structures may be disposed to extend along sidewalls of bitline BL and the sidewalls of bitline capping pattern BC. A pair of spacer structures disposed on both sides of a bitline structure BLS may have an asymmetric shape based on the bitline structure BLS. Each of the spacer structures may include a plurality of spacer layers, and may further include an air spacer in example embodiments.

The lower conductive pattern 150 may be connected to a region of the first active region ACT1, for example, the second impurity region 105b. The lower conductive pattern 150 may be disposed between the bitlines BL. The lower conductive pattern 150 may penetrate a buffer insulating layer 128 and may be connected to the second impurity region 105b of the first active region ACT1. The lower conductive pattern 150 may be in direct contact with the second impurity region 105b. A lower surface of the lower conductive pattern 150 may be disposed on a level lower than a level of an upper surface of substrate 101, and may be disposed on a level higher than a level of a lower surface of the bitline contact pattern DC. The lower conductive pattern 150 may be insulated from the bitline contact pattern DC by the spacer structure SS. The lower conductive pattern 150 may be formed of a conductive material, such as at least one of polycrystalline silicon (Si), titanium (Ti), titanium nitride (TiN), tantalum (Ta), tantalum nitride (TaN), tungsten (W), tungsten nitride (WN), and aluminum (Al). In example embodiments, the lower conductive pattern 150 may include a plurality of layers.

The metal-semiconductor compound layer 155 may be disposed between the lower conductive pattern 150 and the upper conductive pattern 160. For example, when the lower conductive pattern 150 includes a semiconductor material, the metal-semiconductor compound layer 155 may be formed by siliciding a portion of the lower conductive pattern 150. The metal-semiconductor compound layer 155 may include, for example, cobalt silicide (CoSi), titanium silicide (TiSi), nickel silicide (NiSi), tungsten silicide (WSi), or other metal silicide. In example embodiments, the metal-semiconductor compound layer 155 may not be provided.

The upper conductive pattern 160 may be disposed on the lower conductive pattern 150. The upper conductive pattern 160 may extend to a region between the spacer structures SS and may cover an upper surface of the metal-semiconductor compound layer 155. The upper conductive pattern 160 may include a barrier layer 162 and a conductive layer 164. The barrier layer 162 may cover a lower surface and side surfaces of the conductive layer 164. The barrier layer 162 may include at least one of metal nitrides, such as titanium nitride (TiN), tantalum nitride (TaN), and tungsten nitride (WN). The conductive layer 164 may include a conductive material, such as polycrystalline silicon (Si), titanium (Ti), tantalum (Ta), tungsten (W), ruthenium (Ru), copper (Cu), molybdenum (Mo), platinum (Pt), nickel (Ni), cobalt (Co), aluminum (Al), titanium nitride (TiN), tantalum nitride (TaN), and tungsten nitride (WN).

The insulating patterns 165 may be disposed to penetrate the upper conductive pattern 160. The upper conductive pattern 160 may be divided into multiple numbers by the insulating patterns 165. The insulating patterns 165 may include at least one of an insulating material, for example, silicon oxide, silicon nitride, and silicon oxynitride.

The etch stop layer 168 may cover the insulating patterns 165 between the first electrode structures 170. Etch stop layer 168 may also extend further into an interfacial region (not illustrated). The etch stop layer 168 may be in contact with a lower region of side surfaces of the first electrode structures 170. The etch stop layer 168 may be disposed below support patterns SP1, SP2, and SP3. An upper surface of the etch stop layer 168 may include a portion in direct contact with the dielectric layer 176. For example, the etch stop layer 168 may include at least one of silicon nitride and silicon oxynitride.

The first electrode structures 170 may be disposed on the upper conductive patterns 160. The first electrode structures 170 may penetrate the etch stop layer 168 and may be in contact with the upper conductive patterns 160. The first electrode structures 170 may have a form of a pillar, but example embodiments thereof are not limited thereto. The first electrode structures 170 may include at least one of niobium nitride (NbN), niobium oxide (NbOx), polycrystalline silicon (Si), iridium (Ir), titanium (Ti), titanium nitride (TiN), titanium silicide nitride (TiSiN), tantalum (Ta), tantalum nitride (TaN), tungsten (W), tungsten nitride (WN), and aluminum (Al), or combinations thereof, metal nitrides, and metal compounds.

Referring to FIGS. 3 and 4, the first electrode structures 170 may include a first electrode region 172 and a second electrode region 174 disposed on the first electrode region. The second electrode region 174 may include a lower region 174a, an intermediate region 174b, and an upper region 174c. The lower region 174a may be defined as a portion in which the second electrode region 174 is in contact with first electrode region 172, that is, a region including the lower surface 174LS of the second electrode region in contact with the upper surface 172US of the first electrode region. The upper region 174c may be defined as a portion of the second electrode region 174 in contact with the upper support pattern SP3, that is, a region including the upper surface 174US of the second electrode region in contact with the first layer SP3a of the upper support pattern. The intermediate region 174b may be defined as a portion from the lower region 174a to the upper region 174c, that is, a region including the side surface 174SS of the second electrode region. Here, the first electrode region may also have an upper region 172UP including the upper surface 172US in contact with the lower surface 174LS of the second electrode region. In the upper region 172UP, the first electrode region 172 may be in contact with the lower support pattern SP2.

The second electrode region 174 may form a step difference SD with the first electrode region 172. For example, the lower region 174a of the second electrode region may form a step difference with the upper region 172UP of the first electrode region. For example, the lower surface 174LS of the second electrode region may have a width smaller than a horizontal width of the upper surface 172US of the first electrode region. In a cross-sectional view, the horizontal width of the lower surface 174LS of the second electrode region may increase in a direction away in a vertical direction from the upper surface 172US of the first electrode region. According to example embodiments, the horizontal width of the lower surface 174LS of the second electrode region may increase at a constant rate toward the upper region 174c, and accordingly, a side surface 174SS of the second electrode region may have a constant slope based on the lower surface 174LS of the second electrode region.

The upper support pattern SP3 supporting the upper region 174c of the second electrode regions may provide the effect of reducing storage bridge defect SBD occurring between first electrode structures. Here, a distance between the second electrode regions 174 may be defined as a minimum distance between the second electrode regions 174, that is, a distance between the upper regions 174c of the second electrode region. The distance between the second electrode regions 174 may be about 10 nm or more, for example, 10 nm to 20 nm, 10 nm to 18 nm, or 10 nm to 15 nm.

The dielectric layer 176 may cover a side surface and an upper surface of each of the first electrode structures 170 on a surface of the first electrode structures 170. As the second electrode region 174 and the first electrode region 172 forms a step difference SD, the dielectric layer 176 may have a predetermined or alternatively, desired step difference around the step difference SD. The dielectric layer 176 may be disposed between the first electrode structures 170 and the second electrode structures 178. The dielectric layer 176 may cover upper and lower surfaces of support patterns SP1, SP2, and SP3. The dielectric layer 176 may cover an upper surface of the etch stop layer 168.

The dielectric layer 176 may include a high dielectric material, silicon oxide, silicon nitride, or a combination thereof. However, in example embodiments, the dielectric layer 176 may be formed of oxide, nitride, silicide, oxynitride, or silicooxynitride including at least of fluorine (F)-doped titanium (Ti), tantalum (Ta), hafnium (Hf), aluminum (Al), zirconium (Zr), and lanthanum (La), or combinations thereof.

The second electrode structure 178 may be disposed on the dielectric layer 176. The second electrode structure 178 may fill a space between the plurality of first electrode structures 170 and a space between support patterns SP1, SP2, and SP3. Although not illustrated, the dielectric layer 176 and the second electrode structure 178 may extend further into an interfacial region. The second electrode structure 178 may include a conductive material.

The second electrode structure 178 may include a single layer or a plurality of layers. In example embodiments, the second electrode structure 178 may be in direct contact with the dielectric layer 176 and may include a first material layer formed along the dielectric layer 176 and a second material layer covering the first material layer. The first material layer may include a doped semiconductor, a metal, a conductive metal nitride, a metal-semiconductor compound, a conductive metal oxide, or a combination thereof. The second material layer may include silicon material or silicon-germanium material. For example, the second material layer may include a doped silicon material or a doped silicon-germanium material.

In example embodiments, the second electrode structure 178 may further include a protective material layer which may reduce or prevent natural oxidation of the second electrode structure 178 and oxidation by the dielectric layer 176. For example, the protective material layer may be covered by the first material layer and may be in direct contact with the dielectric layer 176. The protective material layer may include at least one of metal, metal-silicon oxide, metal-silicon nitride, or metal-silicon oxynitride.

Support patterns SP1, SP2, and SP3 may support the first electrode structures 170 having a high aspect ratio. The support patterns SP1, SP2, and SP3 may be spaced apart from the substrate 101 in a direction perpendicular to an upper surface of the substrate 101. The support patterns SP1, SP2, and SP3 may be in contact with the first electrode structures 170 and may extend in a direction parallel to the upper surface of the substrate 101.

For example, the support patterns SP1, SP2, and SP3 may include lower support patterns SP1, an intermediate support pattern SP2, and an upper support pattern SP3.

The lower support patterns SP1 and the intermediate support pattern SP2 may support the first electrode regions 172. For example, the intermediate support pattern SP2 may be in contact with a side surface of the upper region 172UP of the first electrode regions may support the upper region 172UP of the first electrode regions. Each of the lower support patterns SP1 and the intermediate support pattern SP2 may include, for example, at least one of silicon nitride, silicon oxynitride, or a similar material.

The upper support patterns SP3 may be a layer supporting the second electrode region 174. The upper support patterns SP3 may be in contact with an upper region 174c of the second electrode regions. The upper support patterns SP3 may include a first layer SP3a and a second layer SP3b on the first layer covering at least a portion of the upper surface 174US and the side surface 174SS of the second electrode region.

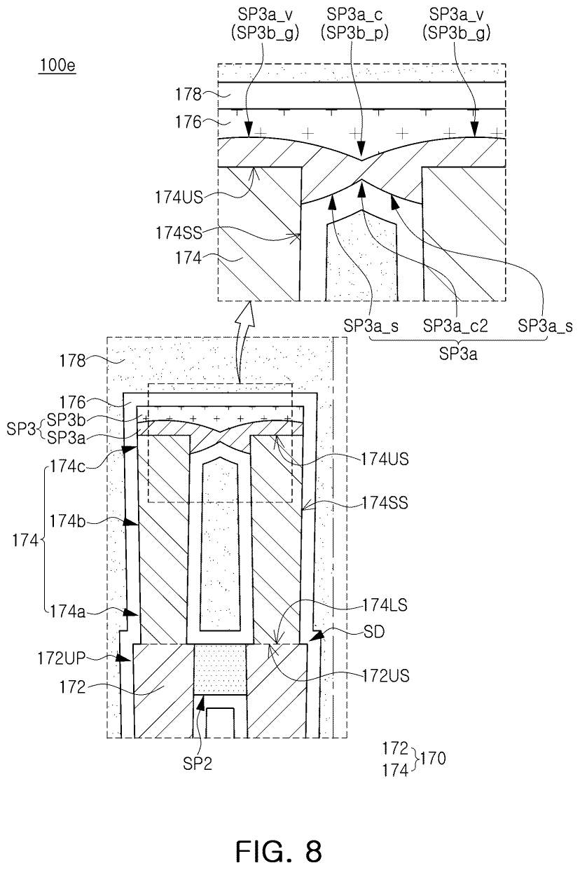

The first layer SP3a may include a convex portion SP3a_v, a concave portion SP3a_c, and a flat portion SP3a_f. The convex portion SP3a_v and the concave portion SP3a_c may be formed on the second electrode region 174. The convex portion SP3a_v may be convex in a direction perpendicular to the upper surface 174US of the second electrode regions. The concave portion SP3a_c may be concave formed between the second electrode regions 174 or on the flat portion SP3a_f by extending the convex portion SP3a_v in the first direction X. The level L_SP3a_c of the concave portion may be higher than a level of the upper surface level L_174US of the second electrode regions. The flat portion SP3a_f may be formed between the second electrode regions 174. The level L_SP3a_f of the flat portion may be lower than a level of the upper surface level 174US_L of the second electrode regions. According to example embodiments, the first layer SP3a may have curved portions between the second electrode regions 174 (see FIG. 8).

The second layer SP3b may be disposed on the first layer SP3a. The second layer SP3b may include a groove portion SP3b_g and a protrusion portion SP3b_p. The groove portion SP3b_g of the second layer may correspond to the convex portion SP3a_v of the first layer, and the protrusion portion SP3b_p of the second layer may correspond to the concave portion SP3a_c of the first layer. Accordingly, the groove portion SP3b_g of the second layer may be in contact with the convex portion SP3a_v of the first layer and may have a shape recessed in a direction perpendicular to the upper surface 174US of the second electrode regions. The protrusion portion SP3b_p of the second layer may be in contact with the concave portion SP3a_c of the first layer and may have a shape protruding in a direction toward the flat portion SP3a_f of the first layer.

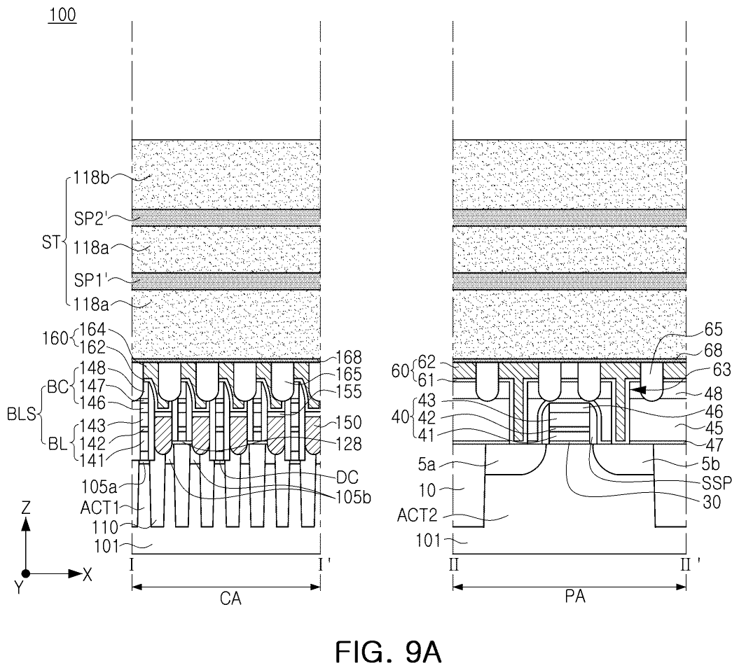

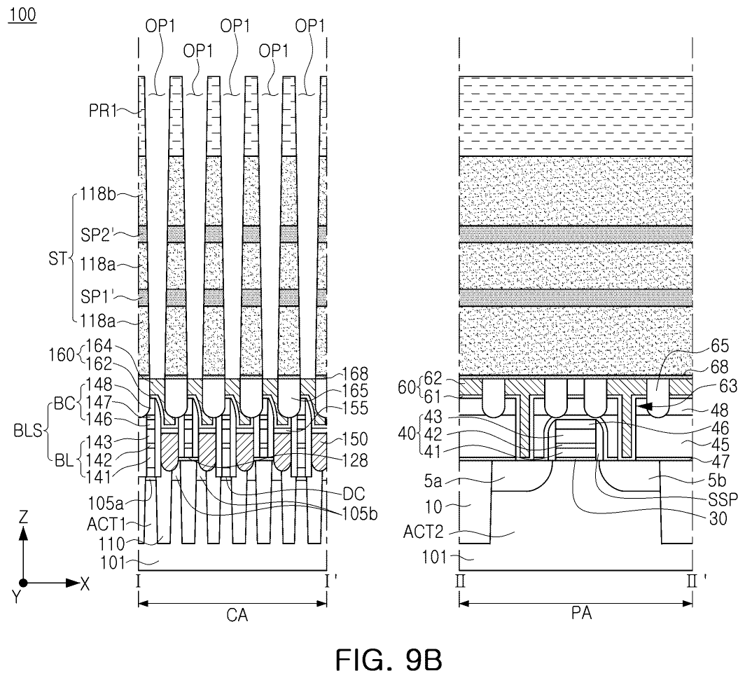

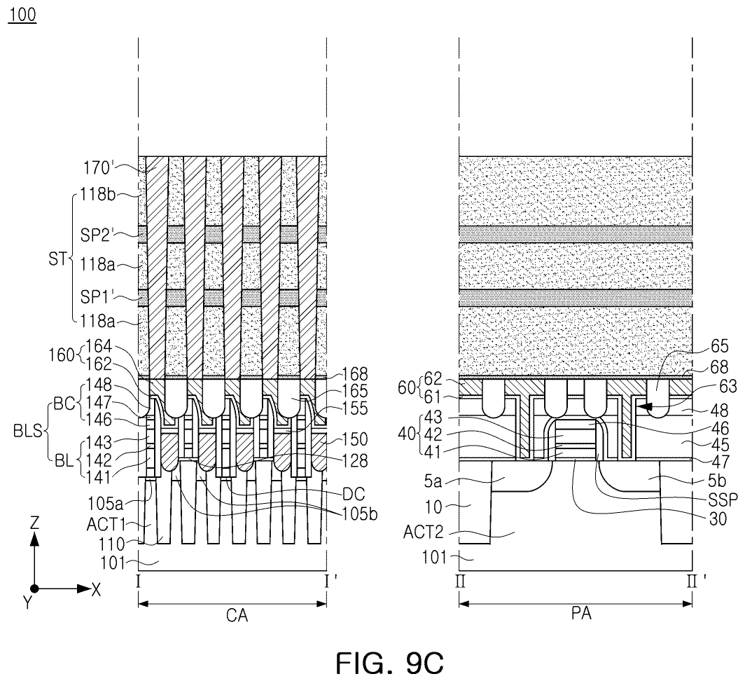

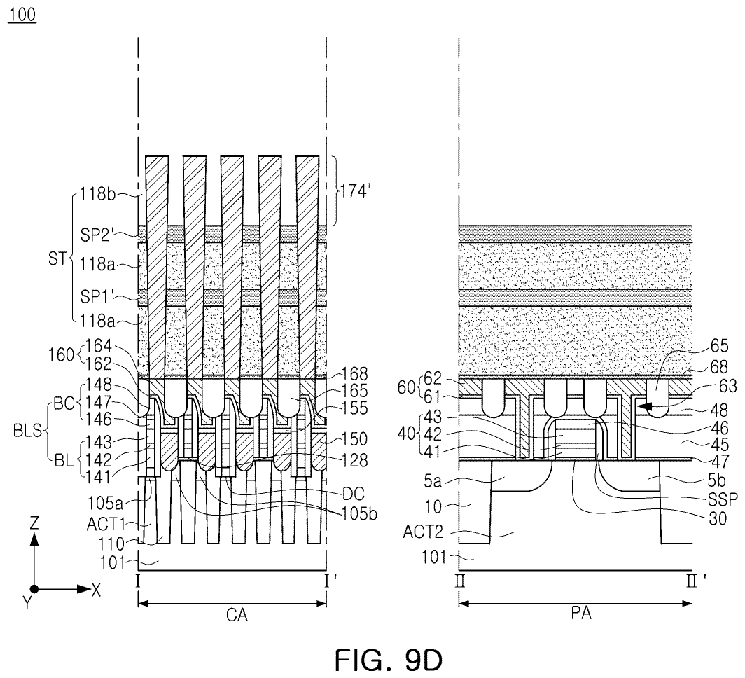

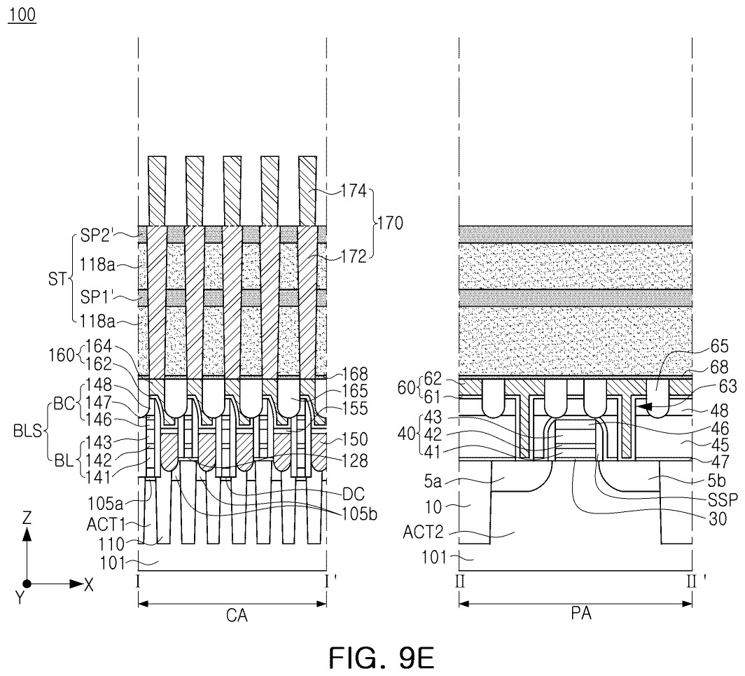

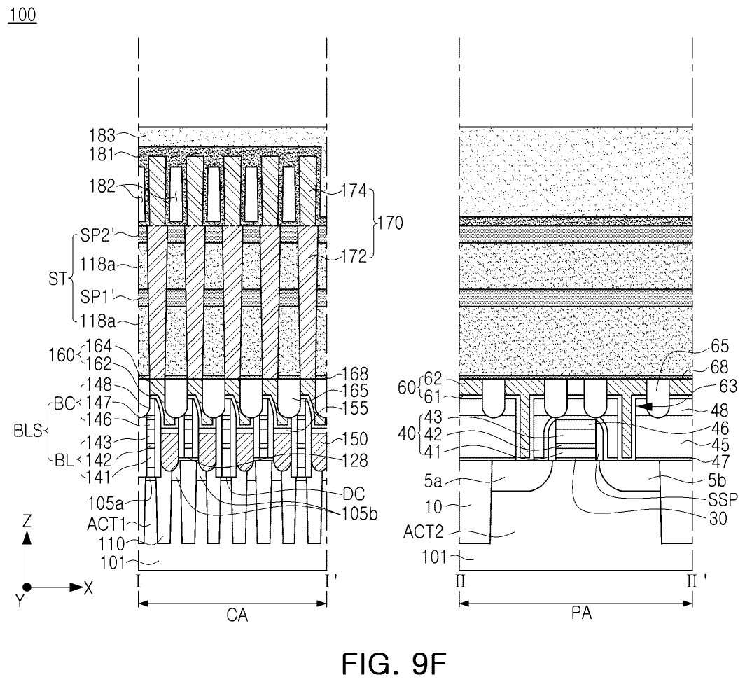

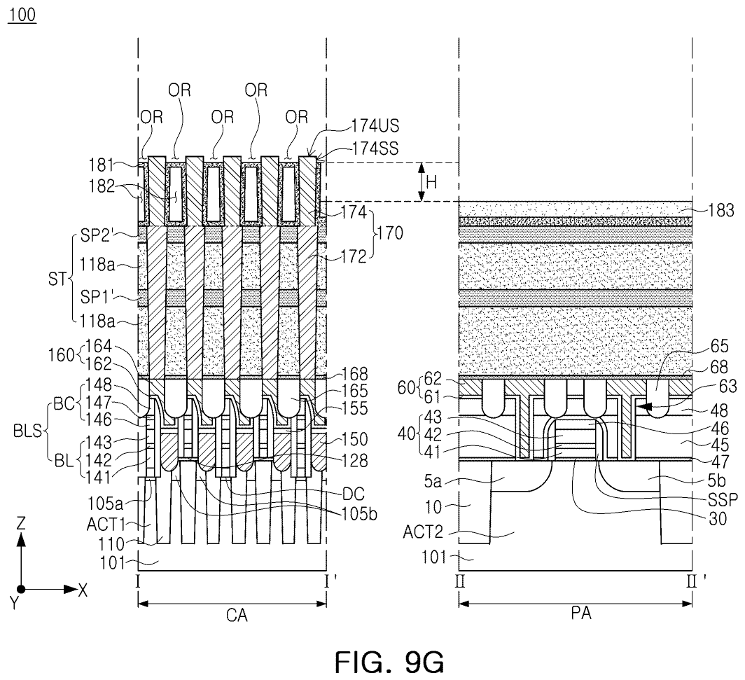

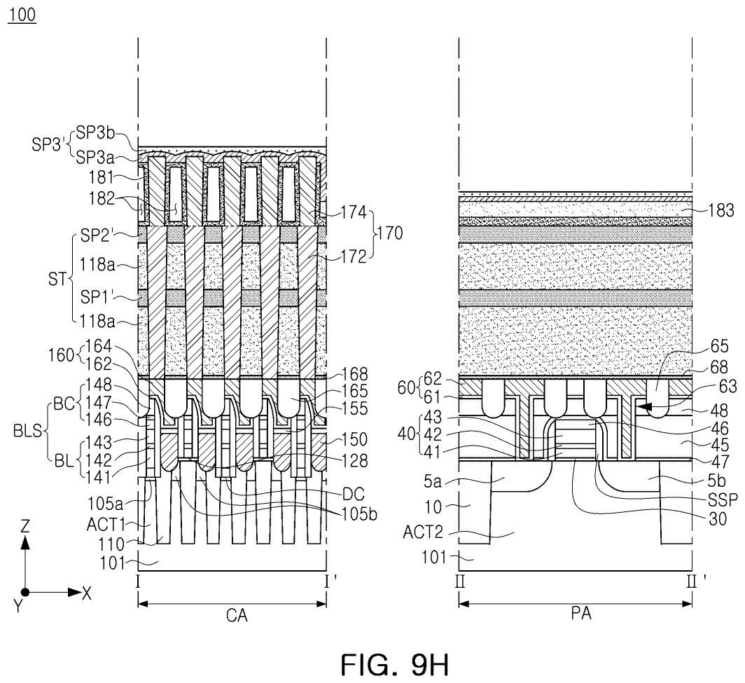

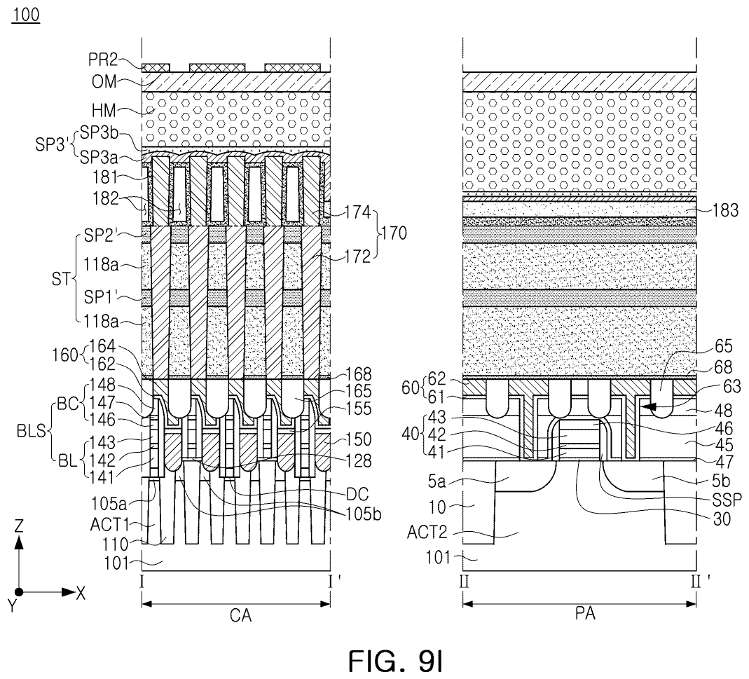

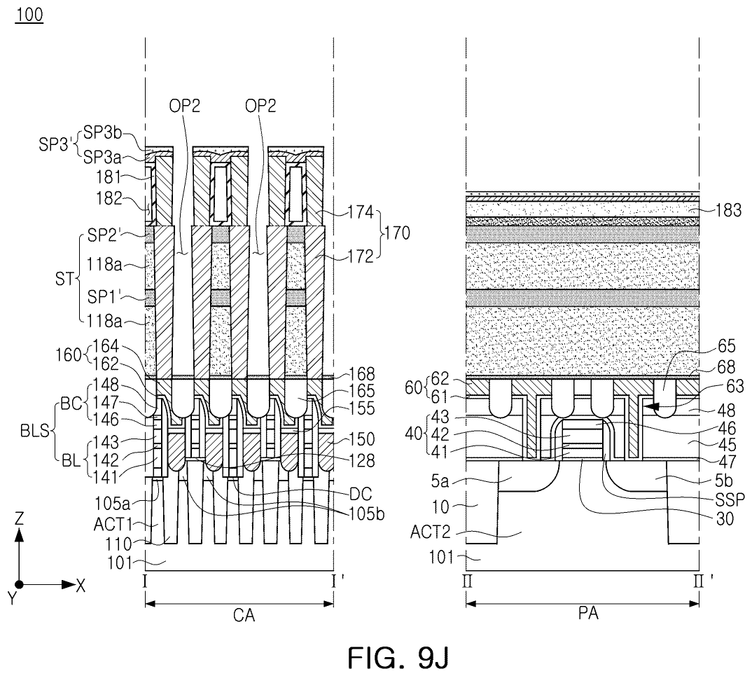

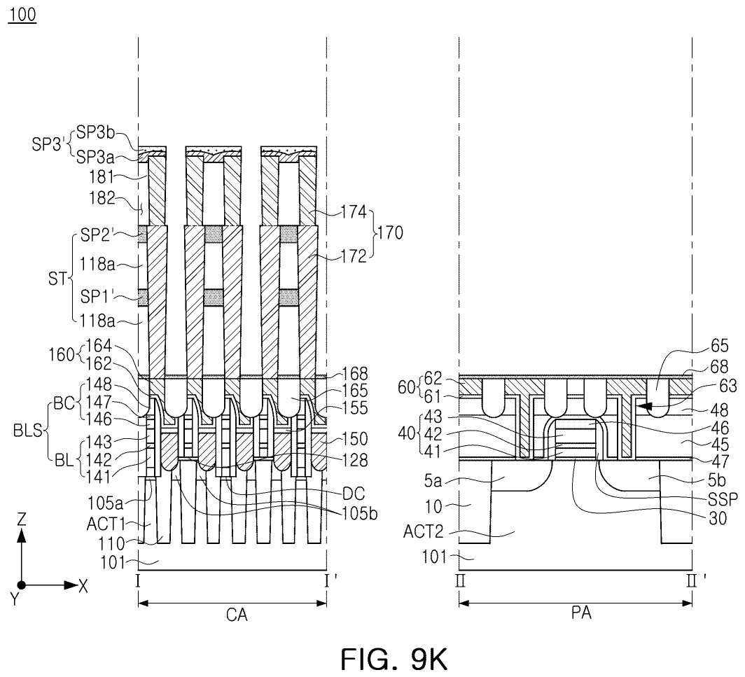

The second layer SP3b may include a material different from that of the first layer SP3a. The first layer SP3a may include silicon nitride. The first layer SP3a may include a material such as SiN, for example, but example embodiments thereof are not limited thereto. Referring to FIG. 9H together, at least a portion of the upper surface 174US and side surface 174SS of the second electrode region exposed by the plurality of open regions OR may be covered by the first layer SP3a including silicon nitride, the exposed films of the upper surface 174US and the side surface 174SS may be protected. The second layer SP3b may include silicon carbonitride. The second layer SP3b may include a material such as SiCN, but example embodiments thereof are not limited thereto. Since the first layer SP3a and the second layer SP3b include different materials, boundaries therebetween may be distinct.

A thickness of the intermediate support pattern SP2 disposed between the upper regions 172UP of the first electrode region may be greater than a thickness of the upper support pattern SP3 disposed on upper surfaces of the second electrode regions 174.

Referring to FIG. 2, in a plan diagram viewed from above, the first electrode structures 170 may have a regular arrangement. In example embodiments, the first electrode structures 170 may be spaced apart from each other by a predetermined or alternatively, desired distance in the first direction X and may be disposed in a zigzag pattern in the second direction Y. For example, the first electrode structures 170 may be disposed in a honeycomb structure. However, the arrangement of first electrode structures 170 is not limited thereto.

A through-hole pattern may be disposed between the plurality of first electrode structures 170 adjacent to each other. In example embodiments, as illustrated in semiconductor device 100 in FIG. 1, a through-hole pattern may be disposed between four adjacent first electrode structures 170. However, the through-hole pattern is not limited thereto.

The semiconductor device 100 may further include a lower interlayer insulating layer 186 covering the second electrode structures 178, and an upper interlayer insulating layer 188 on the lower interlayer insulating layer 186. Although not illustrated, the lower interlayer insulating layer 186 may be in contact with a side surface of the second electrode structures 178 in an interfacial region. The lower interlayer insulating layer 186 may also be in contact with the dielectric layer 176. The upper interlayer insulating layer 188 may be disposed on the lower interlayer insulating layer 186. The lower interlayer insulating layer 186 and the upper interlayer insulating layer 188 may include silicon oxide, silicon nitride, silicon oxynitride, or a combination thereof. In example embodiments, the lower interlayer insulating layer 186 and the upper interlayer insulating layer 188 may include silicon oxide, and even though the lower interlayer insulating layer 186 includes the same material as that of the upper interlayer insulating layer 188, a boundary therebetween may be distinct, and may be parallel to an upper surface of substrate 101, for example.

The semiconductor device 100 may further include a cell contact plug CCP, an interlayer insulating layer ILD and a plurality of upper contact plug 92. The cell contact plug CCP may penetrate the upper interlayer insulating layer 188 and may be connected to the data storage structure CAP. For example, the cell contact plug CCP may penetrate the upper interlayer insulating layer 188 and may be connected to the second electrode structure 178. A lower surface of the cell contact plug CCP may be disposed on a level lower than a level of an upper surface of the second electrode structure 178. An upper surface of the cell contact plug CCP may be coplanar with an upper surface of the upper interlayer insulating layer 188. The cell contact plug CCP may include a barrier layer CCPa and a conductive layer CCPb on the barrier layer CCPa. A side surface of the cell contact plug CCP may be in contact with the lower interlayer insulating layer 186 and the upper interlayer insulating layer 188.

The interlayer insulating layer ILD may be disposed on the upper interlayer insulating layer 188. The interlayer insulating layer ILD may cover the cell contact plug CCP and the upper interlayer insulating layer 188. The interlayer insulating layer ILD may include silicon oxide.

The plurality of upper contact plugs 92 may penetrate the interlayer insulating layer ILD, and at least one of the plurality of upper contact plugs 92 may be connected to the cell contact plug CCP. The plurality of upper contact plug 92 may include a barrier layer 90 and a conductive layer 91 on the barrier layer 90, respectively. Lower surfaces of the plurality of upper contact plug 92 may be flat, for example, parallel to an upper surface of the substrate 101. Lower surfaces of the plurality of upper contact plug 92 may be disposed on the same level.

The barrier layer CCPa and barrier layer 90 may include a metal nitride such as titanium nitride (TiN). The conductive layer CCPb and the conductive layer 91 may include a conductive material such as tungsten (W) and tungsten nitride (WN).

Referring to FIGS. 1 and 3, the semiconductor device 100 may further include a device isolation layer 10, a second active region ACT2, a first peripheral impurity region 5a and a second peripheral impurity region 5b in the peripheral circuit region PA. The device isolation layer 10 may be an insulating layer extending downwardly from an upper surface of the substrate 3 and may define the second active region ACT2. The first peripheral impurity region 5a and the second peripheral impurity region 5b may be spaced apart from each other with the peripheral gate structure 40 therebetween.

The device isolation layer 10 may include silicon oxide, silicon nitride, silicon oxynitride, or a combination thereof, and may include a single layer or a plurality of layers. The first and second peripheral impurity regions 5a and 5b may be provided as a source/drain region of a transistor formed by the peripheral gate structure 40. The first and second peripheral impurity regions 5a and 5b may include impurities having a conductivity-type opposite to that of the substrate 101.

The semiconductor device 100 may further include a peripheral gate dielectric layer 30 and a peripheral gate structure 40 disposed on the substrate 101 in the peripheral circuit region PA. The peripheral gate structure 40 may be formed as a structure and a material similar to that of the bitline BL.

The peripheral gate structure 40 may include a first conductive pattern 41, a second conductive pattern 42, and/or a third conductive pattern 43 sequentially stacked on the peripheral gate dielectric layer 30 of the substrate 101. The peripheral gate dielectric layer 120 may include silicon oxide, silicon nitride, or a high-k material. The high-K material may indicate a dielectric material having a dielectric constant higher than that of silicon oxide. The first conductive pattern 41, the second conductive pattern 42 and the third conductive pattern 43 of the peripheral gate structure 40 may include the same material as those of the first conductive pattern 141, the second conductive pattern 142 and the third conductive pattern 143 of the bitline BL, respectively. The first peripheral capping pattern 46 may be disposed on the peripheral gate structure 40. The first peripheral capping pattern 46 may include the same material as that of the first capping pattern 146 of the bitline capping pattern BC.

The semiconductor device 100 may further include a peripheral gate spacer SSP, a second peripheral capping pattern 47, an interlayer insulating layer 45 and a third peripheral capping pattern 48 in the peripheral circuit region PA. The peripheral gate spacer SSP may cover a side surface of the peripheral gate structure 40. For example, peripheral gate spacers SSP may be spaced apart from each other with the peripheral gate structure 40 therebetween, and may cover side surfaces of the first conductive pattern 41, the second conductive pattern 42, the third conductive pattern 43 and the first peripheral capping pattern 46.

The second peripheral capping pattern 47 may cover the substrate 101, the peripheral gate spacer SSP, and the peripheral gate structure 40, and may be formed conformally. The interlayer insulating layer 45 may partially cover the second peripheral capping pattern 47. An upper surface of the interlayer insulating layer 45 may be coplanar with an upper surface of the second peripheral capping pattern 47. The third peripheral capping pattern 48 may cover the interlayer insulating layer 45 and the second peripheral capping pattern 47.

The second peripheral capping pattern 47 and the third peripheral capping pattern 48 may include the same material as those of the second capping pattern 147 and the third capping pattern 148 of the bitline capping pattern BC, respectively, and may include, for example, silicon nitride. The interlayer insulating layer 45 may include silicon oxide.

The semiconductor device 100 may further include a peripheral plug 63 and a peripheral interconnection 60 electrically connected to the first and second peripheral impurity regions 5a and 5b in the peripheral circuit region PA. The peripheral plugs 63 may penetrate the interlayer insulating layer 45 and may be disposed adjacent to the peripheral gate structure 40 and may be in contact with the first and second peripheral impurity regions 5a and 5b. The peripheral interconnection 60 may be disposed on the third peripheral capping pattern 48 and the peripheral plug 63 and may extend in the first direction. In example embodiments, the peripheral interconnection 60 may be formed integrally with the peripheral plug 63. For example, the peripheral interconnection 60 may include a barrier layer 61 and a conductive layer 62, and the barrier layer 61 and the conductive layer 62 may extend vertically downwardly and may form a peripheral plug 63. In some example embodiments, the peripheral interconnection 60 may not be formed integrally with the peripheral plug 63.

The semiconductor device 100 may further include an insulating pattern 65 disposed between the peripheral interconnections 60. The insulating patterns 65 may spatially isolate the peripheral interconnections 60 from each other and may electrically insulate the peripheral interconnections 60 from each other.

The semiconductor device 100 may further include an etch stop layer 68 disposed on the peripheral interconnections 60. The etch stop layer 68 may be formed integrally with the etch stop layer 168. For example, the etch stop layer 68 may be formed by extending the etch stop layer 168 to the peripheral circuit region PA.

The semiconductor device 100 may further include a peripheral contact plug PCP and an upper contact plug 95 disposed on the peripheral interconnections 60. The peripheral contact plug PCP may penetrate the upper interlayer insulating layer 188, the lower interlayer insulating layer 186 and the etch stop layer 68 and may be in contact with one of the peripheral interconnections 60. The peripheral contact plug PCP may be electrically connected to the first peripheral impurity region 5a or the second peripheral impurity region 5b through the peripheral interconnection 60 and the peripheral plug 63. An upper surface of the peripheral contact plug PCP may be coplanar with an upper surfaces of the cell contact plug CCP and the upper interlayer insulating layer 188. The peripheral contact plug PCP may include a barrier layer PCPa and a conductive layer PCPb on the barrier layer PCPa.

The upper contact plug 95 may penetrate the interlayer insulating layer ILD, and the upper contact plug 95 may be connected to the peripheral contact plug PCP. The upper contact plug 95 may include a barrier layer 93 and a conductive layer 94 on the barrier layer 93. A lower surface of the upper contact plug 95 may be flat, for example, parallel to an upper surface of substrate 101. A lower surface of the upper contact plug 95 may be disposed on the same level as a level of lower surfaces of the plurality of upper contact plug 92.

The barrier layer PCPa and the barrier layer 93 may include a metal nitride such as titanium nitride (TiN). The conductive layer PCPb and the conductive layer 94 may include a conductive material such as tungsten (W) and tungsten nitride (WN).

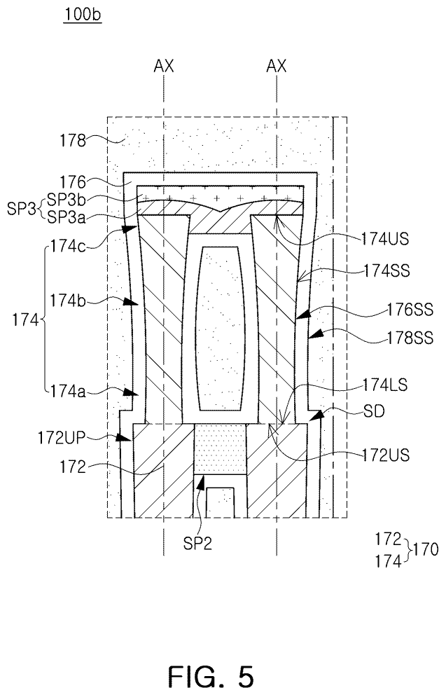

FIG. 5 is an enlarged diagram illustrating a portion of a semiconductor device according to example embodiments.

Referring to FIG. 5, the semiconductor device 100b may be configured the same as or similar to the example described with reference to FIGS. 1 to 4, other than the configuration in which the side surface 174SS of the second electrode region has a curved shape.

Referring to FIGS. 9C and 9D together, at least a portion of a side surface of an exposed upper portion (or ‘preliminary second electrode region 174”) of the first electrode structure 170 may be partially etched, such that a second electrode region 174 having a side surface as in FIG. 5 may be formed.

Referring back to FIG. 5, the side surface 174SS of the second electrode region may have a concave shape in a direction of a central axis AX of the second electrode region. In some example embodiments, since the second electrode region 174 has a high aspect ratio, the concave side surface portion may be formed closer to the central axis AX in a direction from the upper region 174c to the lower region 174a of the second electrode region.

Accordingly, the dielectric layer portion 176SS disposed on the side surface 174SS of the second electrode region and the second electrode structure portion 178SS disposed on the dielectric layer portion 176SS may also have a curved shape, in a cross-sectional view. For example, the dielectric layer portion 176SS and the second electrode structure portion 178SS may have a convex shape in the central axis AX direction.

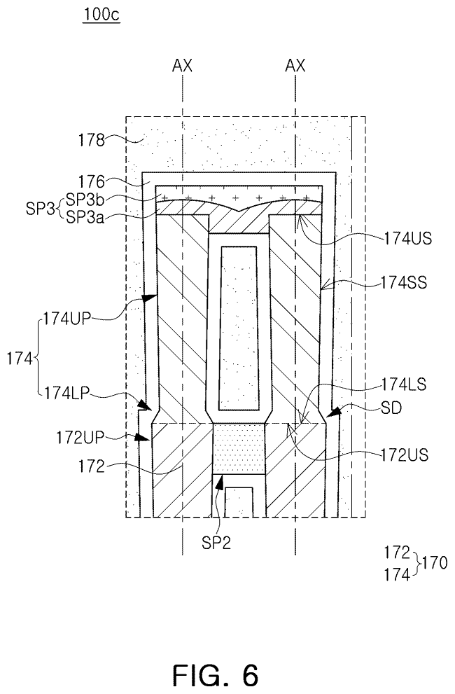

FIG. 6 is an enlarged diagram illustrating a portion of a semiconductor device according to example embodiments.

Referring to FIG. 6, the semiconductor device 100c may be configured the same as or similar to the example described with reference to FIGS. 1 to 4, other than the configuration in which a portion in which a horizontal width of the second electrode region 174 gradually decreases in a direction away from the upper surface 172US of the first electrode region and increases.

Referring to FIGS. 9C and 9D together, since the exposed upper portion (or ‘preliminary second electrode region 174″) of the first electrode structure 170 has a high aspect ratio, the preliminary second electrode region 174’ may be etched such that a step difference SD may be formed in a position higher than a boundary surface of the preliminary second electrode region 174′ and the first electrode region 170.

Referring again to FIG. 6, the second electrode region 174 may include portions of which a horizontal width may decrease and increase toward the third direction (Z-direction). For example, the second electrode region 174 may include a lower portion 174LP and a lower portion 174LP of which a horizontal width decreases toward the third direction (Z-direction), and an upper portion 174UP of which a width increases again in a direction toward the lower portion 174LP. A reduction rate of the horizontal width of the lower portion 174LP in the third direction (Z-direction) may be greater than a increase rate of the horizontal width of the upper portion 174UP. Accordingly, a slope formed by a side surface of the upper portion 174UP with the central axis AX of the second electrode region may be gentler than a slope formed by a side surface of the lower portion 174LP with the central axis AX of the second electrode region. In a different view, a slope formed by a side surface of the upper portion 174UP with the lower surface 174LS of the second electrode region may be steeper than a slope formed by a side surface of a lower portion 174LP with the lower surface 174LS of the second electrode region.

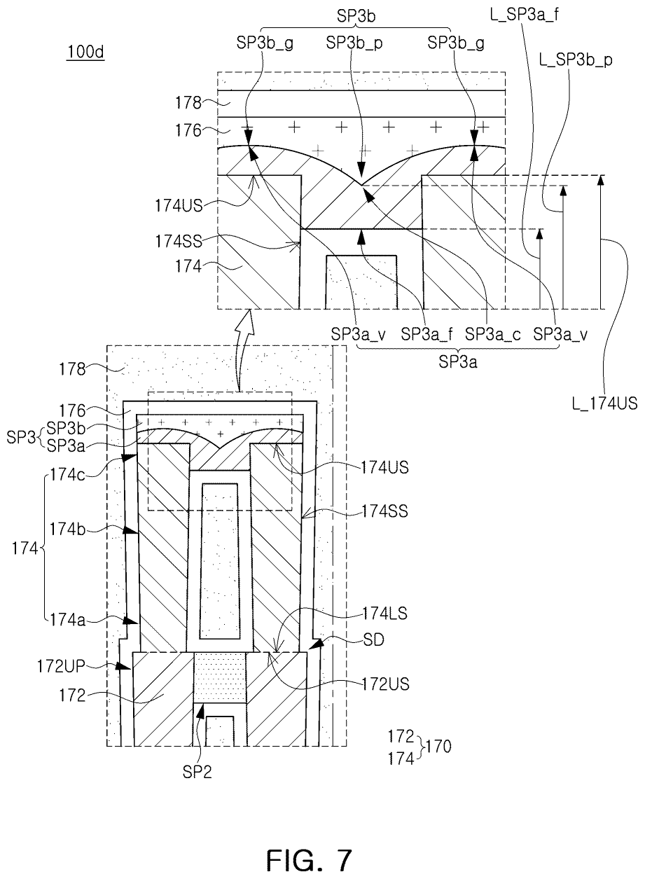

FIG. 7 is an enlarged diagram illustrating a portion of a semiconductor device according to example embodiments.

Referring to FIG. 7, the semiconductor device 100d may be configured the same as or similarly to the example described with reference to FIGS. 1 to 4, other than the configuration in which a level L_SP3a_c of the concave portion is disposed on a level lower than a level of an upper surface level L_174US of the second electrode regions.

Referring to FIG. 9F, at least a portion of the side surface 174 of the second electrode region may be partially etched, thereby forming the second electrode region 174 having a side surface as in FIG. 7. Accordingly, a difference between the level L_SP3a_f of the flat portion and the upper surface level L_174US of the second electrode regions may increase, and accordingly, the level L_SP3a_c of the concave portion may be disposed on a level lower than a level of the upper surface level L_174US.

FIG. 8 is an enlarged diagram illustrating a portion of a semiconductor device according to example embodiments.

Referring to FIG. 8, a semiconductor device 100e may be configured the same as or similar to the example described with reference to FIGS. 1 to 4, other than the configuration in which a portion disposed between the second electrode regions 174 of the first layer SP3a has curved portions SP3a_s.

Each of the curved portions SP3a_s may extend in the first direction (X-direction) from the side surface 174SS of the second electrode regions. Each of the curved portions SP3a_s may be in contact with each other between the second electrode regions 174 and may form a concave portion SP3a_c2 (or ‘second concave portion’). In some example embodiments, the second concave portion SP3a_c2 formed between the second electrode regions 174 may be formed to oppose the concave portion SP3a_c (or ‘first concave portion’) formed on the second electrode regions 174.

FIGS. 9A to 9K are vertical cross-sectional diagrams illustrating a method of manufacturing a semiconductor device according to example embodiments.

Referring to FIG. 9A, a mold structure ST may be formed on a lower structure including a substrate 101, a wordline, and a bitline structure BLS.

The mold structure ST may be formed by conformally forming an etch stop layer 168 on the lower structure, and alternately stacking mold layers 118 and preliminary lower and intermediate support patterns SP1′ and SP2′ including a lower mold layer 118a and an upper portion mold layer 118b on the etch stop layer 168. The mold structure ST may be disposed in a cell region CA and a peripheral circuit region PA. Although not illustrated, the mold structure ST may also be disposed in an interfacial region between the cell region CA and the peripheral circuit region PA.

Referring to FIG. 9B, the first photoresist layer PR1 may be formed on the mold structure ST. Thereafter, a photo mask may be aligned on the first photoresist layer PR1, and a plurality of first openings OP1 penetrating through the first photoresist layer PR1, the mold structure ST, and the etch stop layer 168 may be formed such that the upper conductive pattern 160 may be exposed.

Referring to FIG. 9C, in the cell region CA, the preliminary first electrode structures 170′ may be formed in the plurality of first openings OP1. The preliminary first electrode structures 170′ may be formed by filling a conductive material in the plurality of first openings OP1. The first photoresist layer PR1 may be removed after the preliminary first electrode structures 170′ are formed.

Referring to FIG. 9D, in the cell region CA, the upper portion mold layer 118b may be selectively removed to expose an upper region of the preliminary first electrode structures 170′ and a surface of the preliminary lower support pattern SP2′. The upper region of the preliminary first electrode structures 170′ may be referred to as the preliminary structure of the second electrode regions 174 (or ‘preliminary second electrode regions 174″) formed as in FIG. 9E.

Referring to FIG. 9E, as the preliminary second electrode regions 174’ according to FIG. 9D are etched by an etching process, first electrode structures 170 including second electrode regions 174 and first electrode regions 172 may be formed.

The second electrode regions 174 may be formed by wet etching the preliminary second electrode regions 174′ according to FIG. 9D. Accordingly, a step difference SD may be formed between the first electrode regions 172 and the second electrode regions 174 (see FIG. 4).

Referring to FIG. 9F, in the cell region CA, the first oxide film layer 181 may be conformally formed along a surface of the preliminary lower support pattern SP2′ and the second electrode regions 174. The first oxide film layer 181 may also be formed conformally on the preliminary lower support pattern SP2′ of the peripheral circuit region PA.

The first oxide film layer 181 may be formed by an atomic layer deposition (ALD) technique. A plurality of hollow regions 182 in which the first oxide film layer 181 is not formed may be formed between the second electrode regions 174.

A second oxide film layer 183 may be further formed on the first oxide film layer 181 across the cell region CA and the peripheral circuit region PA. The second oxide film layer 183 may be formed by a physical vapor deposition (PVD) technique.

Referring to FIG. 9G, a portion of the first oxide film layer 181 and the second oxide film layer 183 may be removed to form a plurality of open regions OR exposing the upper region 174c of the second electrode regions. The plurality of open regions OR may be formed by an etching process.

In the plurality of open regions OR, a surface of the first oxide film layer 181, the upper surface 174US of the upper region 174c of the second electrode regions, and at least a portion of the side surface 174SS may be exposed. A depth of each of the plurality of open regions OR may be varied depending on variables such as a concentration of an etchant used in the etching process and the time of exposure to the etchant. Accordingly, the side surface 174SS of the upper region 174c of the second electrode regions may be further exposed.

After the etching process, a height difference H may be formed in the cell region CA and the peripheral circuit region PA. The height difference H may be formed due to a difference in etching rates between the first oxide film layer 181 and the second oxide film layer 183 because the first oxide film layer 181 formed by atomic layer deposition is superior and denser than the second oxide film layer 183 formed by physical vapor deposition.

Referring to FIG. 9H, a preliminary upper support pattern SP3 including a first layer SP3a and a second layer SP3b may be formed across the cell region CA and the peripheral circuit region PA.

The first layer SP3a may cover at least a portion of a surface of the first oxide film layer 181, the upper surface 174US of the second electrode regions, and the side surface 174SS exposed as in FIG. 9G, in the plurality of open regions OR. Referring to FIG. 4 together, the first layer SP3a may be formed to have a convex portion SP3a_v having a convex shape in a vertical direction on the upper surface 174US of the second electrode regions and a concave portion SP3a_c having a concave shape on the surface of the first oxide film layer 181 by a height difference between an upper surface of the second electrode regions 174US and the exposed surface of the first oxide film layer 181. The convex portion SP3a_v and the concave portion SP3a_c may have a continuous shape extending in the horizontal direction.

The second layer SP3b may be formed on the first layer SP3a. Referring to FIG. 4 together, the second layer SP3b may be formed to have a groove portion SP3b_g having a concave shape in contact with the convex portion SP3a_v of the first layer and a protrusion portion SP3b_p having a protruding shape in contact with the concave portion SP3a_c of the first layer.

Referring to FIG. 9I, a hard mask HM may be formed on the preliminary upper support pattern SP3, and a second photoresist layer PR2 may be formed on the hard mask HM.

The hard mask HM may include an amorphous carbon layer ALC. An oxide mask OM may be additionally formed on the hard mask HM. The oxide mask OM may include silicon oxynitride such as SiON, but example embodiments thereof are not limited thereto.

Referring to FIG. 9J, a photo mask may be aligned on the second photoresist layer PR2 according to FIG. 9I, and a plurality of second openings OP2 penetrating the preliminary lower and intermediate support patterns SP1′, SP2′ and the lower mold layers 118 may be formed such that the surface of the etch stop layer 168 may be exposed. Thereafter, the hard mask HM and the second photoresist layer PR2 on the preliminary upper support pattern SP3 may be removed.

Referring to FIG. 9K, the mold structure ST may be removed from the cell region CA and the peripheral circuit region PA. For example, the mold layers 118 and the preliminary support patterns SP1′, SP2′, and SP3′ may be etched in the cell region CA and the peripheral circuit region PA, and the support patterns SP1, SP2, and SP3 may be formed.

Thereafter, the mold layers 118 may be selectively removed, and the side surface of the first electrode structures 170 may be exposed.

Thereafter, as illustrated in FIG. 3, the dielectric layer 176 may be formed conformally along a surface of the first electrode structures 170 and the support patterns SP1, SP2, and SP3. The dielectric layer 176 may also cover the etch stop layer 168 and the etch stop layer 68. Thereafter, a second electrode structure 178 covering the dielectric layer 176 may be formed. The second electrode structure 178 may fill a space between the first electrode structures 170 and may cover the first electrode structures 170 and the support patterns SP1, SP2, and SP3. The first electrode structures 170, the dielectric layer 176 and the second electrode structure 178 may form a data storage structure CAP.

Thereafter, the BEOL process may be performed. Referring again to FIG. 3, a lower interlayer insulating layer 186 covering the etch stop layer 68 and the second electrode structure 178 may be formed, and an upper interlayer insulating layer 188, and a plurality of contact plugs CCP and PCP may be formed on the lower interlayer insulating layer 186. Here, the cell contact plug CCP may penetrate the upper interlayer insulating layer 188 and may be connected to the data storage structure CAP. Thereafter, the interlayer insulating layer ILD and the plurality of upper contact plugs 92 and 95 may be formed.

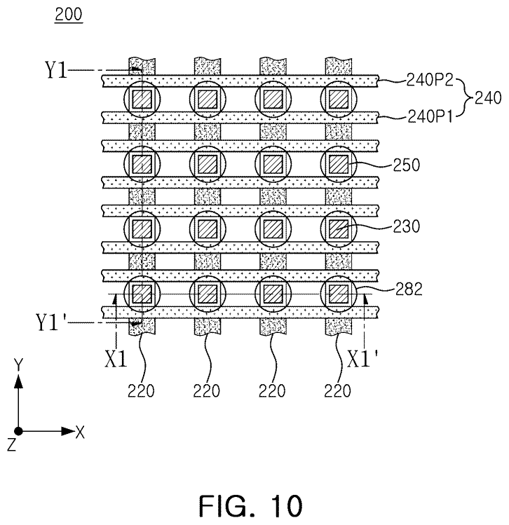

FIG. 10 is a layout diagram illustrating a semiconductor device according to example embodiments.

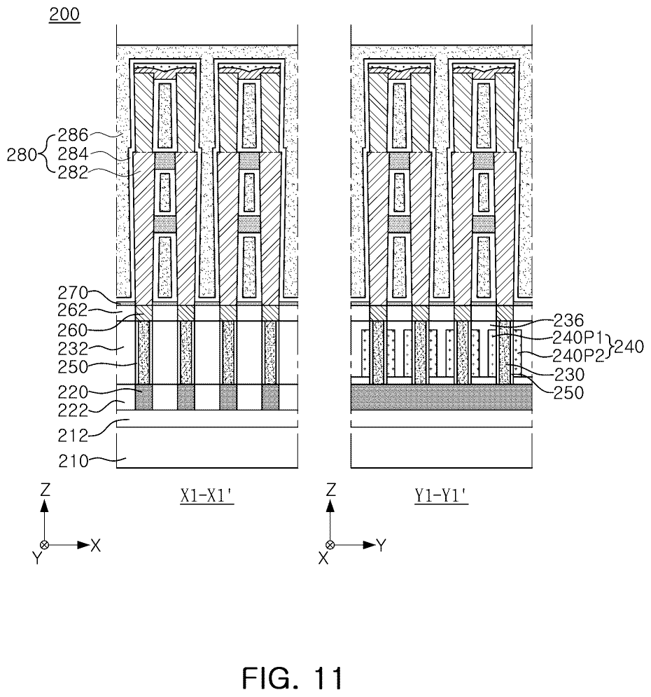

FIG. 11 is a semiconductor device according to example embodiments of the present disclosure, taken along lines X1-X1′ and Y1-Y1′ in FIG. 9.

Referring to FIGS. 10 and 11, the semiconductor device 200 may include a substrate 210, a plurality of first conductive line 220, a channel layer 230, a gate electrode 240, a gate insulating layer 250, and/or a data storage structure 280. The semiconductor device 200 may be a memory device including a vertical channel transistor (VCT). The vertical channel transistor may refer to a structure in which the channel length of the channel layer 230 may extend in the vertical direction from the substrate 210.

A lower insulating layer 212 may be disposed on the substrate 210, and a plurality of first conductive lines 220 may be spaced apart from each other in the first direction (X-direction) and may extend in the second direction (Y-direction) on the lower insulating layer 212. On the lower insulating layer 212, the plurality of first insulating pattern 222 may be disposed to fill a space between the plurality of first conductive line 220. The plurality of first insulating pattern 222 may extend in the second direction (Y-direction), and an upper surface of the plurality of first insulating pattern 222 may be disposed on the same level as a level of an upper surface of the plurality of first conductive line 220. The plurality of first conductive line 220 may function as a bitline of the semiconductor device 200.

In example embodiments, the plurality of first conductive line 220 may include doped polysilicon, metal, conductive metal nitride, conductive metal silicide, conductive metal oxide, or combinations thereof. For example, the plurality of first conductive line 220 may be formed of doped polysilicon, Al, Cu, Ti, Ta, Ru, W, Mo, Pt, Ni, Co, TiN, TaN, WN, NbN, TiAl, TiAIN, TiSi, TiSiN, TaSi, TaSiN, RuTiN, NiSi, CoSi, IrOx, RuOx, or a combination thereof, but example embodiments thereof are not limited thereto. The plurality of first conductive line 220 may include a single layer or multiple layers of the materials described above. In example embodiments, the plurality of first conductive line 220 may include a two-dimensional semiconductor material, for example, the two-dimensional semiconductor material may include graphene, carbon nanotube, or a combination thereof.

The channel layer 230 may be arranged in the form of a matrix in which the channel layers are spaced apart from each other in the first direction (X-direction) and the second direction (Y-direction) on the plurality of first conductive line 220. The channel layer 230 may have a first width in the first direction (X-direction) and a first height in the third direction (Z-direction), and the first height may be larger than the first width. For example, the first height may be about two to ten times the first width, but example embodiments thereof are not limited thereto. A bottom surface of the channel layer 230 may function as a first source/drain region (not illustrated), and a portion of the channel layer 230 between the first and second source/drain regions may function as a channel region (not illustrated). The first source/drain region and the second source/drain region may be vertically spaced apart from each other, and the channel region may be a vertical channel region.

In example embodiments, the channel layer 230 may include an oxide semiconductor, for example, the oxide semiconductor may be InxGayZnzO, InxGaySizO, InxSnyZnzO, InxZnyO, ZnxO, ZnxSnyO, ZnxOyN, ZrxZnySnzO, SnxO, HfxInyZnzO, GaxZnySnzO, Alx ZnySnzO, YbxGayZnzO, InxGayO, or a combination thereof. The channel layer 230 may include a single layer or multiple layers of the oxide semiconductor. In some examples, the channel layer 230 may have a bandgap energy greater than that of silicon. For example, the channel layer 230 may have a bandgap energy of approximately 1.5 eV to 5.6 eV. For example, the channel layer 230 may have optimal channel performance when the channel layer 230 has a bandgap energy of about 2.0 eV to 4.0 eV. For example, the channel layer 230 may be polycrystalline or amorphous, but example embodiments thereof are not limited thereto. In example embodiments, the channel layer 230 may include a two-dimensional semiconductor material, and for example, the two-dimensional semiconductor material may include graphene, carbon nanotube, or a combination thereof.

The gate electrode 240 may extend in the first direction (X-direction) on both sidewalls of the channel layer 230. The gate electrode 240 may include a first sub-gate electrode 240P1 opposing the first sidewall of the channel layer 230, and a second sub-gate electrode 240P2 opposing the second sidewall opposite to the first sidewall of the channel layer 230. As a channel layer 230 is disposed between the first sub-gate electrode 240P1 and the second sub-gate electrode 240P2, the semiconductor device 200 may have a dual gate transistor structure. However, example embodiments thereof are not limited thereto, and the second sub-gate electrode 240P2 may not be provided, and only the first sub-gate electrode 240P1 opposing the first sidewall of the channel layer 230 may be formed, such that a single gate transistor structure may be implemented.

The gate electrode 240 may include doped polysilicon, metal, conductive metal nitride, conductive metal silicide, conductive metal oxide, or a combination thereof. For example, the gate electrode 240 may be formed of doped polysilicon, Al, Cu, Ti, Ta, Ru, W, Mo, Pt, Ni, Co, TiN, TaN, WN, NbN, TiAl, TiAIN, TiSi, TiSiN, TaSi, TaSiN, RuTiN, NiSi, CoSi, IrOx, RuOx, or a combination thereof, but example embodiments thereof are not limited thereto.

The gate insulating layer 250 may surround a sidewall of the channel layer 230 and may be interposed between the channel layer 230 and the gate electrode 240. For example, as illustrated in FIG. 11, the entire sidewall of the channel layer 230 may be surrounded by the gate insulating layer 250, and a portion of the sidewall of the gate electrode 240 may be in contact with the gate insulating layer 250. In other example embodiments, the gate insulating layer 250 may extend in the extension direction (e.g., first direction (X-direction)) of the gate electrode 240, and among the sidewalls of the channel layer 230, only two sidewalls may be in contact with the gate insulating layer 250.

In example embodiments, the gate insulating layer 250 may be formed of a silicon oxide film, a silicon oxynitride film, a high-k dielectric film having a dielectric constant higher than that of a silicon oxide film, or a combination thereof. The high-K dielectric layer may be formed of metal oxide or metal oxynitride. For example, a high-K dielectric layer usable as the gate insulating layer 250 may be formed of HfO2, HfSiO, HfSiON, HfTaO, HfTIO, HfZrO, ZrO2, Al2O3, or a combination thereof, but example embodiments thereof are not limited thereto.

On the plurality of first insulating pattern 222, the plurality of second insulating pattern 232 may extend in the second direction (Y-direction), and a channel layer 230 may be disposed between two adjacent second insulating patterns 232 among the plurality of second insulating pattern 232. Also, the first filling layer 234 and the second filling layer 236 may be disposed in a space between two adjacent second insulating patterns 232 and between two adjacent channel layers 230. The first filling layer 234 may be disposed on a bottom surface of a space between two adjacent channel layers 230, and the second filling layer 236 may be formed to fill the other space between two adjacent channel layers 230 on the first filling layer 234. An upper surface of the second filling layer 236 may be disposed on the same level as a level of an upper surface of the channel layer 230, and the second filling layer 236 may cover an upper surface of the gate electrode 240. Alternatively, the plurality of second insulating pattern 232 may be formed as a material layer continuous with the plurality of first insulating pattern 222, or the second filling layer 236 may be formed as a material layer continuous with the first filling layer 234.

The storage contact 260 may be disposed on the channel layer 230. The storage contact 260 may be disposed to vertically overlap the channel layer 230, and may be arranged in a matrix form in which the storage contacts 260 may be spaced apart from in the first direction (X-direction) and the second direction (Y-direction). The storage contact 260 may be formed of doped polysilicon, Al, Cu, Ti, Ta, Ru, W, Mo, Pt, Ni, Co, TiN, TaN, WN, NON, TiAl, TiAIN, TiSi, TiSiN, TaSi, TaSiN, RuTiN, NiSi, CoSi, IrOx, RuOx, or a combination thereof, but example embodiments thereof are not limited thereto. The upper portion insulating layer 262 may surround a sidewall of the storage contact 260 on the plurality of second insulating pattern 232 and the second filling layer 236.

The etching stop film 270 may be disposed on the upper portion insulating layer 262, and the data storage structure 280 may be disposed on the etching stop film 270. The data storage structure 280 may include a first electrode structure 282, a dielectric layer 284, and a plate electrode 286.

The first electrode structure 282 may penetrate the etching stop film 270 and may be electrically connected to an upper surface of the storage contact 260. The first electrode structure 282 may be formed as a pillar type structure extending in the third direction (Z-direction), but example embodiments thereof are not limited thereto. In example embodiments, the first electrode structure 282 may be disposed to vertically overlap the storage contact 260 and may be arranged in a matrix form in which the first electrode structure 282 may be spaced apart from in the first direction (X-direction) and the second direction (Y-direction). Alternatively, a landing pad (not illustrated) may be further disposed between the storage contact 260 and the first electrode structure 282, such that the first electrode structure 282 may be arranged in a hexagonal shape.

Example embodiments are not necessarily mutually exclusive. For example, some example embodiments may include one or more features described with reference to one or more figures, and may also include one or more other features described with reference to one or more other figures.

According to the aforementioned example embodiments, a semiconductor device including a capacitor having improved reliability may be provided.

While the example embodiments have been illustrated and described above, it will be including as apparent to those skilled in the art that modifications and variations may be made without departing from the scope in the example embodiments as defined by the appended claims.

What is claimed is:

1. A semiconductor device, comprising:
a lower structure including conductive regions;
a capacitor including first electrode structures electrically connected to the conductive regions of the lower structure, a dielectric layer covering the first electrode structures, and a second electrode structure on the dielectric layer; and
an upper support pattern in contact with the first electrode structures,
wherein each of the first electrode structures includes:
a first electrode region extending vertically; and
a second electrode region extending upwardly from the first electrode region and having a side surface not vertically aligned with a side surface of the first electrode region, and
wherein the upper support pattern includes:
a first layer covering upper surfaces of the second electrode regions of the first electrode structures and connected to each other; and
a second layer on the first layer and including a material different from a material of the first layer.

2. The semiconductor device of claim 1,
wherein, in each of the first electrode structures, a width of a lower region of the second electrode regions has a width less than a width of an upper region of the first electrode regions, and
wherein a width of at least a portion of the second electrode regions increases in a direction away from the first electrode region.

3. The semiconductor device of claim 2, wherein the side surfaces of the second electrode regions are inclined with respect to upper surfaces of the first electrode regions.

4. The semiconductor device of claim 2, wherein at least a portion of the side surface of the second electrode region has a concave shape in a direction toward a vertical central axis of the second electrode region.

5. The semiconductor device of claim 1, wherein the second electrode region includes:
a lower portion of which a width decreases in a direction away from an upper surface of the first electrode region; and
an upper portion of which a width increases in a direction away from the lower portion.

6. The semiconductor device of claim 5, wherein a slope of a side surface of the upper portion of the second electrode region is steeper than a slope of the lower portion of the second electrode region.

7. The semiconductor device of claim 1, wherein a distance between the second electrode regions is greater than a distance between upper portions of the first electrode regions.

8. The semiconductor device of claim 1, wherein a distance between the second electrode regions is about 10 nm to about 15 nm.

9. The semiconductor device of claim 1,
wherein the first layer covers at least a portion of an upper surface and a side surface of the second electrode region,
wherein the first layer includes, on the second electrode regions:
convex portions configured to be convex in a direction perpendicular to an upper surface of the second electrode regions; and
a concave portion formed by the convex portions extending in a horizontal direction and in contact with each other.

10. The semiconductor device of claim 9, wherein the first layer has a flat portion having a flat surface between side surfaces of the second electrode regions.

11. The semiconductor device of claim 9, wherein an end of the concave portion is on a level higher than a level of the upper surface of the second electrode regions.

12. The semiconductor device of claim 9, wherein an end of the concave portion is on a level lower than a level of the upper surface of the second electrode regions.

13. The semiconductor device of claim 1,
wherein the first layer covers at least a portion of upper surfaces and side surfaces of the second electrode regions, and
wherein the first layer includes:
convex portions configured to be convex in a direction perpendicular to the upper surface of the second electrode regions;
a first concave portion formed by the convex portions extending in the horizontal direction and in contact with each other; and
curved portions between at least portions of side surfaces of the second electrode regions.

14. The semiconductor device of claim 13,
wherein each of the curved portions extends in a horizontal direction from at least a portion of side surfaces of the second electrode regions, and
wherein the curved portions are in contact with each other and form a second concave portion opposing the first concave portion.

15. The semiconductor device of claim 1, wherein the first layer includes silicon nitride and the second layer includes silicon carbonitride.

16. A semiconductor device, comprising:
a lower structure;
a capacitor on the lower structure, wherein the capacitor includes first electrode structures, a dielectric layer covering the first electrode structures, and a second electrode structure on the dielectric layer; and
an upper support pattern in contact with the first electrode structures,
wherein each of the first electrode structures includes:
a first electrode region extending vertically; and
a second electrode region on the first electrode region,
wherein the upper support pattern includes a first layer covering upper surfaces of the second electrode regions of the first electrode structures and side surfaces of an upper region of the second electrode region and connected to each other, and
wherein the first layer has convex portions having a convex upper surface in a vertical direction away from an upper surface of the lower structure and a concave portion having a concave upper surface between the convex portions.

17. The semiconductor device of claim 16,
wherein the upper support pattern further includes a second layer on the first layer, and
wherein the second layer includes groove portions in contact with the convex portions of the first layer and a protrusion portion between the groove portions and in contact with the concave portion.

18. The semiconductor device of claim 16,
wherein lower surfaces of the second electrode regions have a horizontal width smaller than a width of each of upper surfaces of the first electrode regions, and
wherein a horizontal distance between the second electrode regions deceases in a direction away from the lower surfaces of the second electrode regions, the direction perpendicular to the lower surfaces, and
wherein the horizontal distance is at least about 10 nm or more.

19. The semiconductor device of claim 17, wherein the first layer and the second layer include different materials.

20. A semiconductor device, comprising:
a lower structure including a conductive region on a substrate;
first electrode structures on a lower structure, electrically connected to the conductive region of the lower structure, and extending in a vertical direction;
support patterns in contact with the first electrode structures;
a dielectric layer covering the first electrode structures and the support pattern; and
a second electrode structure on the dielectric layer,
wherein each of the first electrode structures includes a first electrode region and a second electrode region on the first electrode region,
wherein the support patterns include:
an intermediate support pattern in contact with side surfaces of upper regions of the first electrode regions of the first electrode structures; and
an upper support pattern in contact with upper surfaces of the second electrode regions of the first electrode structures and side surfaces of upper regions of the second electrode regions of the first electrode structures, and
wherein, in each of the first electrode structures, a minimum width of the second electrode region is less than a width of an upper region of the first electrode region.
